(19) United States
(12) Patent Application Publication
(10) Pub. No.: US 2024/0347674 A1
(43) Pub. Date: Oct. 17, 2024

(54) GROUP III ELEMENT NITRIDE SEMICONDUCTOR SUBSTRATE AND BONDED SUBSTRATE

(71) Applicant: NGK INSULATORS, LTD., Nagoya-shi (JP)

(72) Inventors: Ayumi SAITO, Nagoya-shi (JP); Tomohiko SUGIYAMA, Nagoya-shi (JP)

(21) Appl. No.: 18/751,540

(22) Filed: Jun. 24, 2024

Related U.S. Application Data
(63) Continuation of application No. PCT/JP2023/001469, filed on Jan. 19, 2023.

(30) Foreign Application Priority Data
Feb. 17, 2022 (JP) 2022-022860

(51) Int. Cl. H01L 33/32; H01L 33/00; H01L 33/20

(52) U.S. Cl. CPC H01L 33/32; H01L 33/0093; H01L 33/20

(57) ABSTRACT

A Group-III element nitride semiconductor substrate includes: a first surface; and a second surface. The Group-III element nitride semiconductor substrate has a thickness of 200 μm or more. In one embodiment, the number N of times of light-and-dark switching in a line segment having a length of 2 mm, which is drawn in a crossed-Nicols image obtained by observation of a region including a central portion of a surface of the first surface with a polarizing microscope, is 50 or more.

### CROSS-REFERENCE TO RELATED APPLICATIONS

This application is a continuation under 35 U.S.C. 120 of International Application PCT/JP2023/001469 having the International Filing Date of 19 Jan. 2023 and having the benefit of the earlier filing date of Japanese Application No. 2022-022860, filed on 17 Feb. 2022. Each of the identified applications is fully incorporated herein by reference.

### BACKGROUND OF THE INVENTION

### 1. Field of the Invention

The present invention relates to a Group-III element nitride semiconductor substrate. More specifically, the present invention relates to a Group-III element nitride semiconductor substrate including a main surface and a back surface in a front and back relationship, in which the occurrence of a crack and a fracture can be suppressed.

### 2. Description of the Related Art

A Group-III element nitride semiconductor substrate, such as a gallium nitride (GaN) wafer, an aluminum nitride (AlN) wafer, or an indium nitride (InN) wafer, has been used as each of the substrates of various semiconductor devices (e.g., Patent Literature 1).

A semiconductor substrate includes a first surface and a second surface. When the first surface is defined as a main surface, and the second surface is defined as a back surface, the main surface is typically a Group-III element polar surface, and the back surface is typically a nitrogen polar surface. An epitaxial crystal may be grown on the main surface, and various devices may be produced thereon.

The Group-III element nitride semiconductor substrate has been used as a base substrate of a semiconductor device, such as an LED or an LD.

In a gallium nitride substrate, a crack or a fracture is liable to occur at the time of the production of a device. It has been known that such crack or fracture is more liable to occur as a difference in residual stress in the substrate becomes larger (Patent Literatures 2 to 4).

The Raman analysis of the surface of a substrate has heretofore been used as a method of evaluating a residual stress in the substrate, and the residual stress is evaluated by the wavenumber of a peak corresponding to an E₂^{H} phonon mode. It has been conceived that as a change in wavenumber becomes larger, a change in residual stress becomes larger.

In Patent Literature 2, there is a report of a gallium nitride substrate in which a difference between the maximum value and minimum value of a Raman shift corresponding to an E₂^{H} phonon mode in a region except a region distant inward from the peripheral edge of a surface having an area of 10 cm² or more by up to 5 mm is 0.5 cm⁻¹ or less.

In Patent Literature 3, there is a report of a gallium nitride substrate having a diameter of 150 mm or more in which a difference between the maximum value and minimum value of peak wavenumbers corresponding to E₂^{H} phonon modes at a total of five places, that is, the center of its surface and four places on the peripheral edge thereof is 0.1 cm⁻¹ or more and 1 cm⁻¹ or less.

In Patent Literature 4, there is a report of a gallium nitride substrate having an area of 18 cm² or more in which a difference in Raman shift amount corresponding to an E₂^{H} phonon mode between the position of the center of gravity of its front surface and the position of the center of gravity of its back surface is 0.1 cm⁻¹ or more and 0.5 cm⁻¹ or less, and a difference in Raman shift amount between the position of the center of gravity of the front surface and the peripheral edge thereof is 0.1 cm⁻¹ or more and 0.5 cm⁻¹ or less.

In addition, a cathode luminescence method (CL method) for the surface of a substrate has heretofore been used as a method of evaluating a residual stress in the substrate (Patent Literature 5). The method includes counting a crystal defect affecting the residual stress as a dislocation appearing on the surface of the substrate.

However, a crack and a fracture occurring in a substrate occur not only on the front surface of the substrate but also on the back surface of the substrate or inside the substrate. Accordingly, it has been impossible to achieve sufficient evaluation of a residual stress in the substrate by the related-art substrate surface evaluation method (the Raman analysis or the CL method) by which measurement is performed on the surface of the substrate. Accordingly, it has been impossible to provide a Group-III element nitride semiconductor substrate that is suppressed from causing a crack and a fracture.

### CITATION LIST

### Patent Literature

[PTL 1] JP 2005-263609 A

[PTL 2] JP 4386031 B2

[PTL 3] JP 6405767 B2

[PTL 4] JP 6384229 B2

[PTL 5] JP 2017-057141 A

### SUMMARY OF THE INVENTION

An object of the present invention is to provide a Group-III element nitride semiconductor substrate including a first surface and a second surface, the Group-III element nitride semiconductor substrate being suppressed from causing a crack and a fracture.

[1] According to at least one embodiment of the present invention, there is provided a Group-III element nitride semiconductor substrate. The Group-III element nitride semiconductor substrate includes: a first surface; and a second surface. The Group-III element nitride semiconductor substrate has a thickness of 200 μm or more. In one embodiment of the present invention, the number N of times of light-and-dark switching in a line segment having a length of 2 mm, which is drawn in a crossed-Nicols image obtained by observation of a region including a central portion of a surface of the first surface with a polarizing microscope, is 50 or more.

[2] In another embodiment of the present invention, when the number of times of light-and-dark switching in a line segment having a length of 2 mm, which is drawn in a crossed-Nicols image obtained by observation of a region including a central portion of a surface of the first surface with a polarizing microscope, is represented by N,
the number of times of light-and-dark switching in a line segment having a length of 2 mm, which is drawn in a crossed-Nicols image obtained by observation of a region including a site located in a rightward direction from the central portion when the surface of the first surface is viewed from a planar direction, the site being distant from an outer periphery of the first surface by 10 mm, with the polarizing microscope, is represented by “a”,
the number of times of light-and-dark switching in a line segment having a length of 2 mm, which is drawn in a crossed-Nicols image obtained by observation of a region including a site located in a leftward direction from the central portion when the surface of the first surface is viewed from the planar direction, the site being distant from the outer periphery of the first surface by 10 mm, with the polarizing microscope, is represented by “b”,
the number of times of light-and-dark switching in a line segment having a length of 2 mm, which is drawn in a crossed-Nicols image obtained by observation of a region including a site located in an upward direction from the central portion when the surface of the first surface is viewed from the planar direction, the site being distant from the outer periphery of the first surface by 10 mm, with the polarizing microscope, is represented by “c”, and
the number of times of light-and-dark switching in a line segment having a length of 2 mm, which is drawn in a crossed-Nicols image obtained by observation of a region including a site located in a downward direction from the central portion when the surface of the first surface is viewed from the planar direction, the site being distant from the outer periphery of the first surface by 10 mm, with the polarizing microscope, is represented by “d”,
a change ratio of each of the “a”, the “b”, the “c”, and the “d” with respect to the N is 20% or less.

[3] In the above-mentioned item [1] or [2], a maximum length between points of the light-and-dark switching is 700 μm or less.

[4] In any one of the above-mentioned items [1] to [3], the substrate has a diameter of 45 mm or more.

[5] According to another aspect of the present invention, there is provided a bonded substrate. The bonded substrate includes: the Group-III element nitride semiconductor substrate of any one of the above-mentioned items [1] to [4]; and a support substrate bonded thereto.

According to the embodiment of the present invention, the Group-III element nitride semiconductor substrate including a first surface and a second surface, the Group-III element nitride semiconductor substrate being suppressed from causing a crack and a fracture, can be provided.

### BRIEF DESCRIPTION OF THE DRAWINGS

FIG. 1 is a typical schematic sectional view of a Group-III element nitride semiconductor substrate according to an embodiment of the present invention.

FIG. 2 is a photograph of a crossed-Nicols image in the crossed-Nicols observation of a region including the central portion of the surface of the first surface of a wafer (1) obtained in Example 1 with a polarizing microscope.

FIG. 3 is a plotted diagram based on the photograph of the crossed-Nicols image in the crossed-Nicols observation of the region including the central portion of the surface of the first surface of the wafer (1) obtained in Example 1 with the polarizing microscope.

FIG. 4 is a photograph of a crossed-Nicols image in the crossed-Nicols observation of a region including the central portion of the surface of the first surface of a wafer (C1) obtained in Comparative Example 1 with a polarizing microscope.

FIG. 5 is a plotted diagram based on the photograph of the crossed-Nicols image in the crossed-Nicols observation of the region including the central portion of the surface of the first surface of the wafer (C1) obtained in Comparative Example 1 with the polarizing microscope.

### DESCRIPTION OF THE EMBODIMENTS

When the expression “weight” is used herein, the expression may be replaced with “mass” that is commonly used as an SI unit representing a weight.

A Group-III element nitride semiconductor substrate according to an embodiment of the present invention is typically a freestanding substrate formed of a Group-III element nitride crystal. In this description, the term “freestanding substrate” means a substrate that is not deformed or broken by its own weight at the time of its handling, and hence can be handled as a solid. The freestanding substrate may be used as each of the substrates of various semiconductor devices, such as a light-emitting device and a power-controlling device.

The Group-III element nitride semiconductor substrate according to the embodiment of the present invention typically has a wafer shape (substantially complete round shape). However, the substrate may be processed into any other shape such as a rectangular shape as required.

Any appropriate size may be adopted as the size (diameter) of the Group-III element nitride semiconductor substrate according to the embodiment of the present invention to the extent that an effect exhibited by the embodiment of the present invention is not impaired. Such size is, for example, 25 mm (about 1 inch), from 45 mm to 55 mm (about 2 inches), from 95 mm to 105 mm (about 4 inches), from 145 mm to 155 mm (about 6 inches), from 195 mm to 205 mm (about 8 inches), or from 295 mm to 305 mm (about 12 inches). The size (diameter) of the Group-III element nitride semiconductor substrate according to the embodiment of the present invention is preferably 45 mm or more, more preferably 50 mm or more.

The thickness of the Group-III element nitride semiconductor substrate according to the embodiment of the present invention (when the thickness is not constant, the thickness of a site having the largest thickness) is 200 μm or more, preferably from 300 μm to 1,000 μm.

Typical examples of the Group-III element nitride include gallium nitride (GaN), aluminum nitride (AlN), indium nitride (InN), and a mixed crystal thereof. Those nitrides may be used alone or in combination thereof.

The Group-III element nitride is specifically GaN, AlN, InN, GaₓAl₁₋ₓN (1>x>0), GaₓIn₁₋ₓN (1>x>0), AlₓIn₁₋ₓN (1>x>0), or GaₓAl_{y}In_{z}N (1>x>0, 1>y>0, x+y+z=1). Those nitrides may be doped with various n-type dopants or p-type dopants.

Typical examples of the p-type dopants include zinc (Zn), manganese (Mn), Iron (Fe), beryllium (Be), magnesium (Mg), strontium (Sr), and cadmium (Cd). Those dopants may be used alone or in combination thereof.

Typical examples of the n-type dopants include silicon (Si), germanium (Ge), tin (Sn), and oxygen (O). Those dopants may be used alone or in combination thereof.

The plane direction of the Group-III element nitride semiconductor substrate may be set to any one of a c-plane, an m-plane, an a-plane, and a specific crystal plane tilted from each of the c-plane, the a-plane, and the m-plane, and particularly when the plane direction is set to the c-plane, the effect exhibited by the embodiment of the present invention can be expressed to a larger extent. Examples of the specific crystal plane tilted from each of the c-plane, the a-plane, and the m-plane may include so-called semipolar planes, such as a {11-22} plane and a {20-21} plane. In addition, the plane direction is permitted to include not only a so-called just plane vertical to the c-plane, the a-plane, the m-plane, or the specific crystal plane tilted from each of the planes but also an off-angle in the range of ±5°.

The Group-III element nitride semiconductor substrate according to the embodiment of the present invention is a Group-III element nitride semiconductor substrate including a first surface and a second surface. When the first surface is defined as a main surface, and the second surface is defined as a back surface, as long as the plane direction of the Group-III element nitride semiconductor substrate is the c-plane, the main surface is typically a Group-III element polar surface, and the back surface is typically a nitrogen polar surface. However, the main surface may be set to the nitrogen polar surface, and the back surface may be set to the Group-III element polar surface. An epitaxial crystal may be grown on the main surface, and various devices may be produced thereon. The back surface may be held with a susceptor or the like to transfer the Group-III element nitride semiconductor substrate according to the embodiment of the present invention.

In the description of the Group-III element nitride semiconductor substrate according to the embodiment of the present invention, the first surface is described as the main surface, and the second surface is described as the back surface. Accordingly, in this description, the term “main surface” may be replaced with “first surface,” the term “first surface” may be replaced with “main surface,” the term “back surface” may be replaced with “second surface,” and the term “second surface” may be replaced with “back surface.”

The main surface may be a mirror surface or a non-mirror surface. The main surface is preferably a mirror surface.

The main surface is preferably a surface from which an affected layer is substantially removed and which has a small surface roughness in a microscopic region from the viewpoint of obtaining such a semiconductor device that devices to be produced by epitaxially growing device layers have satisfactory characteristics and variations in device characteristics between the devices are reduced.

The back surface may be a mirror surface or a non-

mirror surface.

The term “mirror surface” refers to a surface subjected to mirror processing, the surface being brought into a state in which the roughness and waviness of the surface are reduced to such an extent that light is reflected after the mirror processing, and hence the fact that an object is reflected on the surface subjected to the mirror processing can be visually observed. In other words, the term refers to a surface in a state in which the magnitude of each of the roughness and waviness of the surface after the mirror processing is reduced to such an extent as to be sufficiently negligible with respect to the wavelength of visible light. An epitaxial crystal can be sufficiently grown on the surface subjected to the mirror processing.

Any appropriate method may be adopted as a method for the mirror processing to the extent that the effect exhibited by the embodiment of the present invention is not impaired. An example of such method is a method including performing the mirror processing through use of one, or a combination of two or more, of the following apparatus: a polishing apparatus using a tape; a lapping apparatus using diamond abrasive grains; and a chemical mechanical polishing (CMP) apparatus using a slurry such as colloidal silica and a polishing pad made of a nonwoven fabric. When the affected layer remains on the surface after the processing, the affected layer is removed. As a method of removing the affected layer, there are given, for example, a method including removing the affected layer through use of reactive ion etching (RIE) or a chemical liquid, and a method including annealing the substrate.

The term “non-mirror surface” refers to a surface that is not subjected to mirror processing, and a typical example thereof is a rough surface obtained by surface-roughening treatment.

Any appropriate method may be adopted as a method for the surface-roughening treatment to the extent that the effect exhibited by the embodiment of the present invention is not impaired. Examples of such method include: grinding with abrasive stone; laser texture processing; etching treatment with various chemical liquids and gases; physical or chemical coating treatment; and texturing by machining.

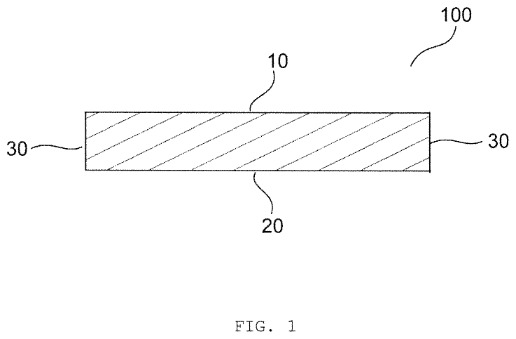

FIG. 1 is a typical schematic sectional view of the Group-III element nitride semiconductor substrate according to the embodiment of the present invention. As illustrated in FIG. 1, a Group-III element nitride semiconductor substrate 100 according to the embodiment of the present invention typically has a main surface (Group-III element polar surface) 10 and a back surface (nitrogen polar surface) 20. The Group-III element nitride semiconductor substrate 100 according to the embodiment of the present invention may have a side surface 30.

An end portion of the Group-III element nitride semiconductor substrate according to the embodiment of the present invention may adopt any appropriate form to the extent that the effect exhibited by the embodiment of the present invention is not impaired. Examples of the shape of the end portion of the Group-III element nitride semiconductor substrate according to the embodiment of the present invention include: a shape in which a main surface side and a back surface side are each chamfered so as to be a flat surface; a shape in which the main surface side and the back surface side are each chamfered in an R-shape; a shape in which only the main surface side of the end portion is chamfered so as to be a flat surface; and a shape in which only the back surface side of the end portion is chamfered so as to be a flat surface.

When the end portion of the Group-III element nitride semiconductor substrate according to the embodiment of the present invention is chamfered, the chamfered portion may be arranged over the one entire round of an outer peripheral portion, or may be arranged only in part of the outer peripheral portion.

The number N of times of light-and-dark switching in a line segment having a length of 2 mm, which is drawn in a crossed-Nicols image obtained by the observation of a region including the central portion of the surface of the first surface of the Group-III element nitride semiconductor substrate according to the embodiment of the present invention with a polarizing microscope, is preferably 30 or more, more preferably 50 or more, still more preferably 80 or more, particularly preferably 100 or more. The upper limit value of the N is desirably as large as possible, and is 300 or less in reality. When the number N of times of the light-and-dark switching in the line segment having a length of 2 mm, which is drawn in the crossed-Nicols image obtained by the observation of the region including the central portion of the surface of the first surface with the polarizing microscope, falls within the above-mentioned ranges, there can be provided a Group-III element nitride semiconductor substrate that is suppressed from causing a crack and a fracture.

The number of times of the light-and-dark switching in the line segment having a length of 2 mm, which is drawn in the crossed-Nicols image obtained by the observation of the region including the central portion of the surface of the first surface with the polarizing microscope, may be measured as described below. That is, first, at the time of the performance of crossed-Nicols observation with the polarizing microscope, observation conditions are adjusted so that light and dark portions may not have the maximum value and minimum value of brightness, respectively. Then, a magnification is set to 50 times or less, and lighting is adjusted so that the entirety of an observation field of view may have even and uniform lightness. After that, an image of the region including the central portion of the surface of the first surface of the substrate is obtained. Ten line segments each having a length of 2 mm are drawn in the resultant image so as to divide the image into 11 equal sections in its Y-axis direction, and for each of the line segments, a position on the line segment is plotted against an axis of abscissa, and brightness on the line segment is plotted against an axis of ordinate. A line corresponding to a brightness of 20% when the maximum brightness and the minimum brightness out of the plotted brightnesses are defined as 100% and 0%, respectively is drawn, and the number of times that brightness plots straddle the line corresponding to a brightness of 20% is counted. In the embodiment of the present invention, the average of the numbers of times of the 10 respective line segments is defined as the number of times of the light-and-dark switching in the line segment having a length of 2 mm, which is drawn in the crossed-Nicols image obtained by the observation of the region including the central portion of the surface of the first surface with the polarizing microscope, and the average represents the frequency at which light and dark regions switch with each other.

The inventors of the present invention have made extensive investigations on the suppression of the occurrence of a crack and a fracture in the Group-III element nitride semiconductor substrate. Then, the inventors have paid attention to the fact that the crack and the fracture occurring in the substrate occur in the entirety of the substrate including not only the front surface of the substrate but also the back surface of the substrate and the inside of the substrate. Further, the inventors have conceived that the crack and the fracture occurring in the substrate result from a residual stress present in the entirety of the substrate. Then, the inventors have paid attention to the fact that the distribution of the residual stress for the entirety of the substrate can be visualized by crossed-Nicols observation with a polarizing microscope. As the number of times of light-and-dark switching in the crossed-Nicols observation of the region including the central portion of the surface of the first surface with the polarizing microscope becomes larger, a fluctuation in stress becomes smaller. Accordingly, the inventors have reached the technical idea that when a Group-III element nitride semiconductor substrate is designed on the basis of the number of times of the light-and-dark switching, there can be provided a novel Group-III element nitride semiconductor substrate that is suppressed from causing a crack and a fracture.

A Group-III element nitride semiconductor substrate according to another embodiment of the present invention has the following feature:
(1) when the number of times of light-and-dark switching in a line segment having a length of 2 mm, which is drawn in a crossed-Nicols image obtained by observation of a region including a central portion of a surface of the first surface with a polarizing microscope, is represented by N,
(2) the number of times of light-and-dark switching in a line segment having a length of 2 mm, which is drawn in a crossed-Nicols image obtained by observation of a region including a site located in a rightward direction from the central portion when the surface of the first surface is viewed from a planar direction, the site being distant from an outer periphery of the first surface by 10 mm, with the polarizing microscope, is represented by “a”,
(3) the number of times of light-and-dark switching in a line segment having a length of 2 mm, which is drawn in a crossed-Nicols image obtained by observation of a region including a site located in a leftward direction from the central portion when the surface of the first surface is viewed from the planar direction, the site being distant from the outer periphery of the first surface by 10 mm, with the polarizing microscope, is represented by “b”,
(4) the number of times of light-and-dark switching in a line segment having a length of 2 mm, which is drawn in a crossed-Nicols image obtained by observation of a region including a site located in an upward direction from the central portion when the surface of the first surface is viewed from the planar direction, the site being distant from the outer periphery of the first surface by 10 mm, with the polarizing microscope, is represented by “c”, and
(5) the number of times of light-and-dark switching in a line segment having a length of 2 mm, which is drawn in a crossed-Nicols image obtained by observation of a region including a site located in a downward direction from the central portion when the surface of the first surface is viewed from the planar direction, the site being distant from the outer periphery of the first surface by 10 mm, with the polarizing microscope, is represented by “d”,
a change ratio of each of the “a”, the “b”, the “c”, and the “d” with respect to the N is preferably 20% or less, more preferably 16% or less, still more preferably 12% or less, particularly preferably 8% or less. When the above-mentioned change ratio of each of the “a”, the “b”, the “c”, and the “d” with respect to the N falls within the above-mentioned ranges, there can be provided a Group-III element nitride semiconductor substrate that is suppressed from causing a crack and a fracture.

The above-mentioned number of times of the light-and-dark switching in the line segment having a length of 2 mm, which is drawn in the crossed-Nicols image obtained by the observation of the region including the site located in the rightward direction from the central portion when the surface of the first surface is viewed from the planar direction, the site being distant from the outer periphery by 10 mm, with the polarizing microscope, the above-mentioned number of times of the light-and-dark switching in the line segment having a length of 2 mm, which is drawn in the crossed-Nicols image obtained by the observation of the region including the site located in the leftward direction from the central portion when the surface of the first surface is viewed from the planar direction, the site being distant from the outer periphery by 10 mm, with the polarizing microscope, the above-mentioned number of times of the light-and-dark switching in the line segment having a length of 2 mm, which is drawn in the crossed-Nicols image obtained by the observation of the region including the site located in the upward direction from the central portion when the surface of the first surface is viewed from the planar direction, the site being distant from the outer periphery by 10 mm, with the polarizing microscope, and the above-mentioned number of times of the light-and-dark switching in the line segment having a length of 2 mm, which is drawn in the crossed-Nicols image obtained by the observation of the region including the site located in the downward direction from the central portion when the surface of the first surface is viewed from the planar direction, the site being distant from the outer periphery by 10 mm, with the polarizing microscope, may each be measured in the same manner as in the above-mentioned number of times of the light-and-dark switching in the line segment having a length of 2 mm, which is drawn in the crossed-Nicols image obtained by the observation of the region including the central portion of the surface of the first surface with the polarizing microscope, by adopting each of the above-mentioned regions instead of the region including the central portion of the surface of the first surface of the substrate as a place at which an image is obtained.

The inventors of the present invention have made extensive investigations on another evaluation method that provides an indicator for the suppression of the occurrence of a crack and a fracture in the Group-III element nitride semiconductor substrate. Then, the inventors have paid attention to the fact that the crack and the fracture occurring in the substrate occur in the entirety of the substrate including not only the front surface of the substrate but also the back surface of the substrate and the inside of the substrate. Further, the inventors have conceived that the crack and the fracture occurring in the substrate result from a residual stress present in the entirety of the substrate. Thus, the inventors have made an investigation on the method by which the entirety of the substrate can be evaluated for its residual stress. As a result, the inventors have paid attention to the fact that a stress distribution can be identified by crossed-Nicols observation with a polarizing microscope. Then, the inventors have reached the following technical idea: when the change ratio of the number of times of light-and-dark switching in the crossed-Nicols observation of each of regions including four sites located in four directions, that is, upward, downward, leftward, and rightward directions from the central portion of the surface of the first surface of the substrate when the surface of the first surface is viewed from a planar direction, the sites being each distant from the outer periphery of the first surface by 10 mm, with the polarizing microscope with respect to the number of times of light-and-dark switching in the crossed-Nicols observation of a region including the central portion of the surface of the first surface with the polarizing microscope is designed so as to be smaller than a predetermined amount, there can be provided a Group-III element nitride semiconductor substrate that is suppressed from causing a crack and a fracture.

With regard to the points of the above-mentioned light-and-dark switching, that is, the points of the light-and-dark switching in the line segment having a length of 2 mm, which is drawn in the crossed-Nicols image obtained by the observation of the region including the central portion of the surface of the first surface with the polarizing microscope, the points of the light-and-dark switching in the line segment having a length of 2 mm, which is drawn in the crossed-Nicols image obtained by the observation of the region including the site located in the rightward direction from the central portion when the surface of the first surface is viewed from the planar direction, the site being distant from the outer periphery by 10 mm, with the polarizing microscope, the points of the light-and-dark switching in the line segment having a length of 2 mm, which is drawn in the crossed-Nicols image obtained by the observation of the region including the site located in the leftward direction from the central portion when the surface of the first surface is viewed from the planar direction, the site being distant from the outer periphery by 10 mm, with the polarizing microscope, the points of the light-and-dark switching in the line segment having a length of 2 mm, which is drawn in the crossed-Nicols image obtained by the observation of the region including the site located in the upward direction from the central portion when the surface of the first surface is viewed from the planar direction, the site being distant from the outer periphery by 10 mm, with the polarizing microscope, and the points of the light-and-dark switching in the line segment having a length of 2 mm, which is drawn in the crossed-Nicols image obtained by the observation of the region including the site located in the downward direction from the central portion when the surface of the first surface is viewed from the planar direction, the site being distant from the outer periphery by 10 mm, with the polarizing microscope, the maximum length between the points in each of the line segments is preferably 700 μm or less, more preferably 200 μm or less, still more preferably 50 μm or less, particularly preferably 20 μm or less. The lower limit value of the above-mentioned maximum length between the points of the switching is desirably as small as possible, and is 0.2 μm or more in reality. When the above-mentioned maximum length between the points of the switching falls within the above-mentioned ranges, there can be provided a Group-III element nitride semiconductor substrate that is further suppressed from causing a crack and a fracture.

The Group-III element nitride semiconductor substrate according to the embodiment of the present invention may be produced by any appropriate method to the extent that the effect exhibited by the embodiment of the present invention is not impaired. A method of producing the Group-III element nitride semiconductor substrate according to the embodiment of the present invention, which is preferred because the effect exhibited by the embodiment of the present invention can be expressed to a larger extent, is described below.

In the method of producing the Group-III element nitride semiconductor substrate according to the embodiment of the present invention, typically, a seed crystal film is formed on the main surface of a base substrate, and a Group-III element nitride layer is formed on the Group-III element polar surface of the seed crystal film. Next, a Group-III element nitride layer (seed crystal film+Group-III element nitride layer) serving as a freestanding substrate is separated from the base substrate. Thus, a freestanding substrate having a main surface and a back surface is obtained.

Any appropriate material may be adopted as a material for the base substrate to the extent that the effect exhibited by the embodiment of the present invention is not impaired. Examples of such material include sapphire, crystal oriented alumina, gallium oxide, AlₓGa₁₋ₓN (0≤x≤1), GaAs, and SiC.

In general, an epi-ready grade base substrate (typically, an epi-ready sapphire substrate) is typically adopted as the base substrate to be used in the production of the Group-III element nitride semiconductor substrate. However, the base substrate to be used in the production of the Group-III element nitride semiconductor substrate according to the embodiment of the present invention may be subjected to washing treatment by any appropriate method before the formation of the seed crystal film. Examples of such washing treatment include APM (SC1) washing (mixed liquid of ammonia and hydrogen peroxide water), HPM (SC2) washing (mixed liquid of hydrochloric acid and hydrogen peroxide water), SPM washing (mixed liquid of sulfuric acid and hydrogen peroxide water), DHF washing (diluted hydrofluoric acid solution), FPM washing (mixed liquid of hydrofluoric acid and hydrogen peroxide water), ultrapure water washing, and ozone water washing. The washing treatment may be preferably performed so that a contaminant may be removed to such an extent that crystal growth is not adversely affected. The removal of the contaminant to such extent can achieve the above-mentioned desired number of times of the light-and-dark switching. The seed crystal film may be more preferably formed on the base substrate immediately after the washing treatment. Such configuration can suppress or substantially eliminate the adhesion of the contaminant until the base substrate is used.

Any appropriate material may be adopted as a material for the seed crystal film to the extent that the effect exhibited by the embodiment of the present invention is not impaired. Examples of such material include AlₓGa₁₋ₓN (0≤x≤1) and InₓGa₁₋ₓN (0≤x≤1). Of those, gallium nitride is preferred.

Any appropriate formation method may be adopted as a method of forming the seed crystal film to the extent that the effect exhibited by the embodiment of the present invention is not impaired. Such formation method is, for example, a vapor growth method, and preferred examples thereof include a metal-organic chemical vapor deposition (MOCVD) method, a hydride vapor phase epitaxy (HVPE) method, a pulsed excitation deposition (PXD) method, a molecular beam epitaxy (MBE) method, and a sublimation method. Of those, a MOCVD method is more preferred as the method of forming the seed crystal film.

The formation of the seed crystal film by the MOCVD method is preferably performed by, for example, depositing a low-temperature grown buffer layer by from 20 nm to 50 nm at from 450° C. to 550° C., and then laminating a film having a thickness of from 2 μm to 4 μm at from 1,000° C. to 1,200° C.

Any appropriate growth direction may be adopted as the growth direction of the Group-III element nitride crystal layer to the extent that the effect exhibited by the embodiment of the present invention is not impaired. Examples of such growth direction include: the normal direction of the c-plane of a wurtzite structure; the normal direction of each of the a-plane and m-plane thereof; and the normal direction of a plane tilted from each of the c-plane, the a-plane, and the m-plane.

Any appropriate formation method may be adopted as a method of forming the Group-III element nitride crystal layer to the extent that the effect exhibited by the embodiment of the present invention is not impaired as long as a layer to be formed by the method has a crystal direction substantially following the crystal direction of the seed crystal film. Examples of such formation method include: gas phase growth methods, such as a MOCVD method, a HVPE method, a PXD method, a MBE method, and a sublimation method; liquid phase growth methods, such as a Na flux method, an ammonothermal method, a hydrothermal method, and a sol-gel method; a powder growth method utilizing solid phase growth of powder; and a combination thereof.

When the Na flux method is adopted as the method of forming the Group-III element nitride crystal layer, the Na flux method is preferably performed in conformity with a production method described in JP 5244628 B2 by appropriately adjusting the conditions and the like so that the effect exhibited by the embodiment of the present invention can be expressed to a larger extent.

The formation of the Group-III element nitride crystal layer by the Na flux method is typically preferably performed as follows: a seed crystal substrate (base substrate+seed crystal film) is arranged in a crucible serving as a growing container under a nitrogen atmosphere; a melt composition containing a Group-III element, metal Na, and as required, a dopant (e.g., an n-type dopant, such as germanium (Ge), silicon (Si), or oxygen (O); or a p-type dopant, such as beryllium (Be), magnesium (Mg), calcium (Ca), strontium (Sr), zinc (Zn), or cadmium (Cd)) is further loaded into the crucible; the crucible is lidded; the lidded crucible is loaded into an external container; the external container is further loaded into a pressure-resistant container; and under a nitrogen atmosphere, after the temperature and pressure of the container are increased, the container is rotated while the temperature and the pressure are retained.

Next, the freestanding substrate including the Group-III element nitride crystal layer may be obtained by separating the Group-III element nitride crystal layer from the base substrate.

Any appropriate method may be adopted as a method of separating the Group-III element nitride crystal layer from the base substrate to the extent that the effect exhibited by the embodiment of the present invention is not impaired. Examples of such method include: a method including causing the Group-III element nitride crystal layer to spontaneously separate from the base substrate through use of a thermal shrinkage difference in a temperature decrease step after the growth of the Group-III element nitride crystal layer; a method including separating the Group-III element nitride crystal layer from the base substrate through chemical etching; a method including separating the Group-III element nitride crystal layer from the base substrate by a laser lift-off method including applying laser light from the back surface side of the base substrate; and a method including separating the Group-III element nitride crystal layer from the base substrate through grinding. In addition, the freestanding substrate including the Group-III element nitride crystal layer may be obtained by slicing the Group-III element nitride crystal layer through utilization of a wire saw or the like.

In the Group-III element nitride crystal layer thus obtained by the Na flux method, it is preferred that a plate surface thereof be flattened by being ground with abrasive stone or the like, and the plate surface be then smoothened, for example, by being lapped with diamond abrasive grains.

Next, the freestanding substrate is shaped into a circular shape having a desired diameter by grinding its outer peripheral portion.

Any appropriate size may be adopted as the size of the freestanding substrate to the extent that the effect exhibited by the embodiment of the present invention is not impaired. Such size is, for example, 25 mm (about 1 inch), from 45 mm to 55 mm (about 2 inches), from 95 mm to 105 mm (about 4 inches), from 145 mm to 155 mm (about 6 inches), from 195 mm to 205 mm (about 8 inches), or from 295 mm to 305 mm (about 12 inches).

Next, the main surface and/or the back surface is subjected to removal processing by, for example, grinding, lapping, or polishing so that the semiconductor substrate is turned into a thin plate having a desired thickness, followed by flattening. Thus, a freestanding substrate is obtained.

At the time of the performance of surface processing, such as grinding, lapping, or polishing, the freestanding substrate is typically bonded to a processing surface plate by, for example, using a wax. At this time, the pressure at which the freestanding substrate is bonded to the processing surface plate, specifically, a pressure to be applied to the freestanding substrate when the freestanding substrate is bonded to the processing surface plate is appropriately adjusted.

The thickness of the freestanding substrate after the polishing (when the thickness is not constant, the thickness of a place having the largest thickness) is preferably 200 μm or more, more preferably from 300 μm to 1,000 μm.

The outer peripheral edge of the freestanding substrate is chamfered through grinding as required. When an affected layer remains on the surface of the main surface of the substrate, the affected layer is substantially removed. In addition, when a residual stress resulting from the affected layer remains on the surface of the back surface thereof, the residual stress is removed. Thus, the Group-III element nitride semiconductor substrate according to the embodiment of the present invention is finally obtained.

In the Group-III element nitride semiconductor substrate according to the embodiment of the present invention, the chamfering may be performed by any appropriate chamfering method to the extent that the effect exhibited by the embodiment of the present invention is not impaired. Examples of such chamfering method include: grinding with a diamond abrasive stone; polishing with a tape; and chemical mechanical polishing (CMP) using a slurry such as colloidal silica and a polishing pad made of a nonwoven fabric.

A crystal can be epitaxially grown on the main surface (Group-III element polar surface) of the Group-III element nitride semiconductor substrate to be obtained, and the formation of a functional layer can provide a functional device.

The epitaxial crystal to be grown on the Group-III element nitride semiconductor substrate to be obtained may be, for example, gallium nitride, aluminum nitride, indium nitride, or a mixed crystal thereof. Specific examples of such epitaxial crystal include GaN, AIN, InN, GaₓAl₁₋ₓN (1>x>0), GaₓIn₁₋ₓN (1>x>0), AlₓIn₁₋ₓN(1>x>0), and GaₓAl_{y}In_{z}N (1>x>0, 1>y>0, x+y+z=1). In addition, examples of the functional layer to be arranged on the Group-III element nitride semiconductor substrate to be obtained include a rectifying device layer, a switching device, and a power semiconductor layer in addition to a light-emitting layer. In addition, the thickness and thickness distribution of the freestanding substrate may be reduced by subjecting the nitrogen polar surface to processing, such as grinding or polishing, after the arrangement of the functional layer on the Group-III element polar surface of the Group-III element nitride semiconductor substrate to be obtained.

A bonded substrate according to an embodiment of the present invention may be obtained by bonding the Group-III element nitride semiconductor substrate to be obtained and a support substrate to each other. That is, the bonded substrate according to the embodiment of the present invention includes the Group-III element nitride semiconductor substrate according to the embodiment of the present invention and the support substrate bonded thereto.

The bonded substrate according to the embodiment of the present invention may further include any appropriate layer to the extent that the effect exhibited by the embodiment of the present invention is not impaired. The kinds, functions, number, combination, arrangement, and the like of such layers may be appropriately determined in accordance with purposes.

Any appropriate thickness may be adopted as the thickness of the support substrate to the extent that the effect exhibited by the embodiment of the present invention is not impaired. The thickness of the support substrate is, for example, from 100 μm to 1,000 μm.

Any appropriate substrate may be used as the support substrate to the extent that the effect exhibited by the embodiment of the present invention is not impaired. The support substrate may include a monocrystalline body, or may include a polycrystalline body.

In the bonded substrate according to the embodiment of the present invention, for example, the joint surface of the Group-III element nitride semiconductor substrate and the joint surface of the support substrate are directly joined to each other. Specifically, the bonded substrate according to the embodiment of the present invention is obtained, for example, as follows: the joint surface of the support substrate and the joint surface of the Group-III element nitride semiconductor substrate are caused to face each other; and the joint surface of the support substrate and the joint surface of the Group-III element nitride semiconductor substrate are subjected to surface activation, and are then joined to each other. After that, a desired epitaxial film may be formed on the film formation surface of the Group-III element nitride semiconductor substrate.

In the bonded substrate according to the embodiment of the present invention, for example, a joining layer may be arranged between the Group-III element nitride semiconductor substrate and the support substrate. Specifically, the bonded substrate according to the embodiment of the present invention is obtained, for example, as follows: the joint surface of the joining layer on the main surface of the support substrate and the joint surface of the Group-III element nitride semiconductor substrate are caused to face each other; and the joint surface of the joining layer and the joint surface of the Group-III element nitride semiconductor substrate are subjected to surface activation, and are then joined to each other. After that, a desired epitaxial film may be formed on the film formation surface of the Group-III element nitride semiconductor substrate. The following may be performed: the joining layer is arranged on the main surface of the Group-III element nitride semiconductor substrate, and the joint surface of the joining layer is directly joined to the joint surface of the support substrate. Alternatively, the following may be performed: a first joining layer is arranged on the main surface of the Group-III element nitride semiconductor substrate, a second joining layer is arranged on the main surface of the support substrate, and the joint surface of the first joining layer is directly joined to the joint surface of the second joining layer.

When the bonded substrate according to the embodiment of the present invention is an embodiment in which the joining layer is arranged between the Group-III element nitride semiconductor substrate and the support substrate, the joining layer is preferably at least one kind selected from the group consisting of: tantalum pentoxide; alumina; aluminum nitride; silicon carbide; sialon; and Si₍₁₋ₓ₎Oₓ (0.008≤x≤0.408). Thus, a joining strength between the support substrate and the Group-III element nitride semiconductor substrate can be further improved.

Sialon is a ceramic obtained by sintering a mixture of silicon nitride and alumina, and has the following composition.

Si_{6-z}Al_{z}O_{z}N_{8-z}

That is, sialon has such composition that alumina is mixed in silicon nitride, and “z” represents the mixing ratio of alumina. “z” more preferably represents 0.5 or more. “z” more preferably represents 4.0 or less.

### EXAMPLES

The present invention is specifically described below by way of Examples. However, the present invention is by no means limited to Examples. Test and evaluation methods in Examples and the like are as described below. The term “part(s)” in the following description means “part(s) by weight” unless otherwise specified, and the term “%” in the following description means “wt %” unless otherwise specified.

### Measurement of Number N (Times) of Times of Light-and-dark Switching in Line Segment having Length of 2 mm, which is drawn in Crossed-Nicols Image obtained by Observation of Region including Central Portion of Surface of First Surface with Polarizing Microscope

DM8000 M manufactured by Leica Microsystems was used as a polarizing microscope.

First, at the time of the performance of crossed-Nicols observation, observation conditions were adjusted so that light and dark portions did not have the maximum value and minimum value of brightness, respectively. Specifically, the settings of exposure and a gain were adjusted, and it was recognized from the brightness histogram of an entire image that all brightness values were more than 0 and less than 255.

Next, a magnification was set to 50 times, and lighting was adjusted so that the entirety of an observation field of view had even and uniform lightness. After that, an image of a region including the central portion of the surface of the first surface of a substrate was taken. At this time, the size of the image to be obtained was set to be 1,824 pixels×1,368 pixels or more.

Ten line segments each having a length of 2 mm were drawn in the resultant image so as to divide the image into 11 equal sections in its Y-axis direction, and for each of the line segments, a position on the line segment was plotted against an axis of abscissa, and brightness on the line segment was plotted against an axis of ordinate. A line corresponding to a brightness of 20% when the maximum brightness and the minimum brightness out of the plotted brightnesses were defined as 100% and 0%, respectively was drawn, and the number of times that brightness plots straddled the line corresponding to a brightness of 20% was counted. The average of the numbers of times of the 10 respective line segments was defined as the number N (times) of times of light-and-dark switching in a line segment having a length of 2 mm, which was drawn in a crossed-Nicols image obtained by the observation of the region including the central portion of the surface of the first surface with the polarizing microscope.

### Measurement of Numbers “a” (Times), “b” (Times), “c” (Times), and “d” (Times) of Times of Light-and-dark Switching in Line Segments each having Length of 2 mm, which are drawn in Crossed-Nicols Images obtained by Observation of Regions including Sites located in Upward, Downward, Leftward, and Rightward Directions from Central Portion when Surface of First Surface is viewed from Planar Direction, the Sites being each distant from Outer Periphery by 10 mm, with Polarizing Microscope

Measurement was performed in the same manner as in the above-mentioned section <Measurement of Number N (Times) of Times of Light-and-dark Switching in Line Segment having Length of 2 mm, which is drawn in Crossed-Nicols Image obtained by Observation of Region including Central Portion of Surface of First Surface with Polarizing Microscope> except that each of four regions including four sites located in the respective upward, downward, leftward, and rightward directions from the central portion when the surface of the first surface was viewed from a planar direction, and being each distant from the outer periphery of the first surface by 10 mm, was adopted as a place at which image taking was performed.

### Calculation of Change Ratio of each of “a”, “b”, “c”, and “d” with Respect to N

The change ratio of the “a” with respect to the N was calculated in accordance with the following equation. The change ratios of the “b”, the “c”, and the “d” with respect to the N were also similarly calculated.

$$Change ratio ( \% ) = \vert ( a - N ) / N \vert \times 100$$

### Occurrence Ratio of Crack and Fracture

The number of places at which a crack and a fracture occurred in the entirety of the substrate of a sample that had been evaluated for the number of times of light-and-dark switching was counted. The crack was observed by dark field-of-view observation with a microscope. The fracture was visually observed. In each of Example and Comparative Example, 12 samples (number of n=12) were subjected to the evaluation, and the occurrence ratio of the crack and the fracture was calculated by dividing the total of the numbers of places at which cracks and fractures occurred in all the samples by the number of samples, that is, 12.

### Example 1

A sapphire substrate (epi-ready grade) was washed so that a contaminant that might affect crystal growth was removed. The sapphire substrate immediately after the washing was used as a base substrate, and a gallium nitride film having a thickness of 2 μm was formed thereon by a MOCVD method. Thus, a seed crystal substrate was produced. The seed crystal substrate was arranged in an alumina crucible in a glove box under a nitrogen atmosphere. Next, metal gallium and metal sodium were loaded into the crucible so that the following ratio was obtained: Ga/(Ga+Na) (mol %)=15 mol %. The crucible was lidded with an alumina plate. The crucible was loaded into an internal container made of stainless steel, and was further loaded into an external container made of stainless steel capable of housing the internal container. The external container was closed with a container lid. The external container was arranged on a rotating table placed on a heating portion in a crystal production apparatus, and a pressure-resistant container storing the external container was lidded and sealed.

Next, the inside of the pressure-resistant container was evacuated to 0.1 Pa or less with a vacuum pump. Subsequently, while an upper-stage heater, a middle-stage heater, and a lower-stage heater were adjusted to perform heating so that a heated space had a temperature of 870° C., a nitrogen gas was introduced from a nitrogen gas cylinder up to 4.0 MPa, and the external container was rotated about a center axis at a speed of 20 rpm in clockwise motion and counterclockwise motion with a constant period. Then, the container was retained under that state for 40 hours. After that, the container was naturally cooled to room temperature and reduced in pressure to atmospheric pressure. After that, the lid of the pressure-resistant container was opened, and the crucible was taken out of the container. Solidified metal sodium in the crucible was removed, and a gallium nitride crystal grown on the seed crystal substrate was collected.

UV laser light was applied from the sapphire substrate side to decompose the gallium nitride crystal on the seed crystal substrate. Thus, the grown gallium nitride crystal was separated from the sapphire substrate.

Next, the separated gallium nitride crystal was ground and polished to produce a wafer (1) serving as a gallium nitride freestanding substrate having a diameter of 50.8 mm and a thickness of 400 μm.

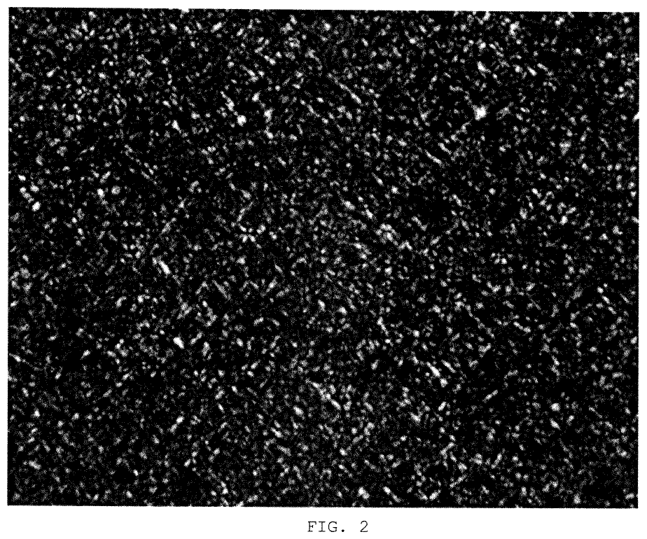

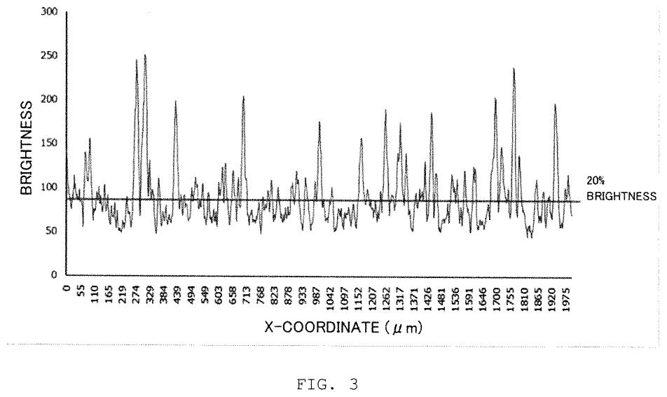

The number N (times) of times of light-and-dark switching in a line segment having a length of 2 mm, which was drawn in a crossed-Nicols image obtained by the observation of a region including the central portion of the surface of the first surface of the wafer (1) with a polarizing microscope, was measured. As a result, a crossed-Nicols image shown in FIG. 2 was obtained. Ten line segments each having a length of 2 mm were drawn in the resultant image so as to divide the image into 11 equal sections in its Y-axis direction, and for each of the line segments, a position on the line segment was plotted against an axis of abscissa, and brightness on the line segment was plotted against an axis of ordinate. A line corresponding to a brightness of 20% when the maximum brightness and the minimum brightness out of the plotted brightnesses were defined as 100% and 0%, respectively was drawn. Thus, 10 plotted diagrams were obtained. FIG. 3 is one plotted diagram out of the 10 plotted diagrams.

The number N (times) of times of the light-and-dark switching was determined from the resultant 10 plotted diagrams. As a result, the N was equal to 137.

Next, the number of times of light-and-dark switching in a line segment having a length of 2 mm, which was drawn in a crossed-Nicols image obtained by the observation of each of regions including sites located in upward, downward, leftward, and rightward directions from the central portion when the surface of the first surface of the wafer (1) was viewed from a planar direction, the sites being each distant from the outer periphery of the first surface by 10 mm, with the polarizing microscope, was measured, and the crossed-Nicols images and plotted diagrams were obtained in the same manner as that described above, followed by the determination of the numbers “a” (times), “b” (times), “c” (times), and “d” (times) of times of the light-and-dark switching. As a result, the “a”, the “b”, the “c”, and the “d” were equal to 144, 127, 141, and 136, respectively, and the change ratios of the “a”, the “b”, the “c”, and the “d” with respect to the N were 5%, 7%, 3%, and 1%, respectively.

Eleven wafers were further produced by the same production method as that for the wafer (1). The number N (times) of times of the light-and-dark switching of each of the resultant 12 wafers was 30 or more, and the change ratio of the number of times of switching in each of the upward, downward, leftward, and rightward directions of the wafer with respect to the number of times of switching in the center thereof was 20% or less. The occurrence ratio of a crack and a fracture in the 12 samples including the wafer (1) was 8%.

### Comparative Example 1

A sapphire substrate (epi-ready grade) was used as a base substrate, and a gallium nitride film having a thickness of 2 μm was formed thereon by a MOCVD method. Thus, a seed crystal substrate was produced. The seed crystal substrate was arranged in an alumina crucible in a glove box under a nitrogen atmosphere. Next, metal gallium and metal sodium were loaded into the crucible so that the following ratio was obtained: Ga/(Ga+Na) (mol %)=15 mol %. The crucible was lidded with an alumina plate. The crucible was loaded into an internal container made of stainless steel, and was further loaded into an external container made of stainless steel capable of housing the internal container. The external container was closed with a container lid. The external container was arranged on a rotating table placed on a heating portion in a crystal production apparatus, and a pressure-resistant container storing the external container was lidded and sealed.

Next, the inside of the pressure-resistant container was evacuated to 0.1 Pa or less with a vacuum pump. Subsequently, while an upper-stage heater, a middle-stage heater, and a lower-stage heater were adjusted to perform heating so that a heated space had a temperature of 870° C., a nitrogen gas was introduced from a nitrogen gas cylinder up to 4.0 MPa, and the external container was rotated about a center axis at a speed of 20 rpm in clockwise motion and counterclockwise motion with a constant period. Then, the container was retained under that state for 40 hours. After that, the container was naturally cooled to room temperature and reduced in pressure to atmospheric pressure. After that, the lid of the pressure-resistant container was opened, and the crucible was taken out of the container. Solidified metal sodium in the crucible was removed, and a gallium nitride crystal grown on the seed crystal substrate was collected.

UV laser light was applied from the sapphire substrate side to decompose the gallium nitride crystal on the seed crystal substrate. Thus, the grown gallium nitride crystal was separated from the sapphire substrate.

Next, the separated gallium nitride crystal was ground and polished to produce a wafer (C1) serving as a gallium nitride freestanding substrate having a diameter of 50.8 mm and a thickness of 400 μm.

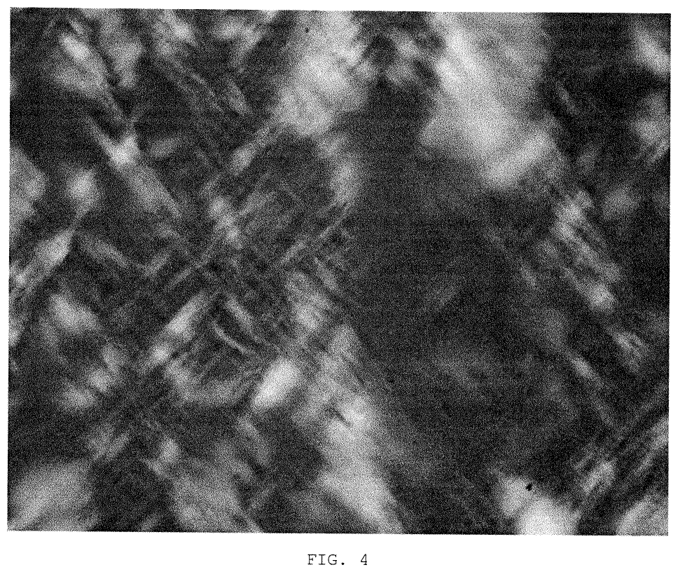

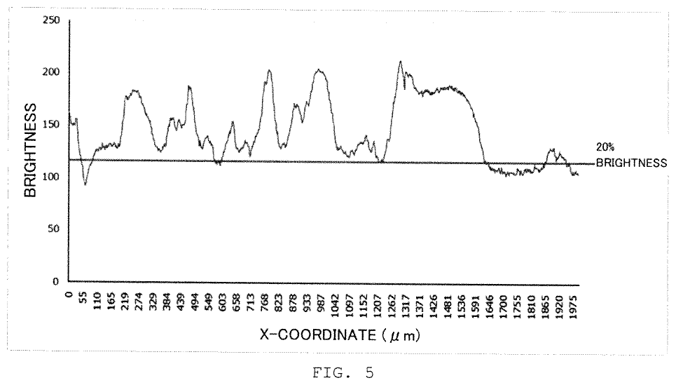

The number N (times) of times of light-and-dark switching in a line segment having a length of 2 mm, which was drawn in a crossed-Nicols image obtained by the observation of a region including the central portion of the surface of the first surface of the wafer (C1) with a polarizing microscope, was measured. As a result, a crossed-Nicols image shown in FIG. 4 was obtained. Ten line segments each having a length of 2 mm were drawn in the resultant image so as to divide the image into 11 equal sections in its Y-axis direction, and for each of the line segments, a position on the line segment was plotted against an axis of abscissa, and brightness on the line segment was plotted against an axis of ordinate. A line corresponding to a brightness of 20% when the maximum brightness and the minimum brightness out of the plotted brightnesses were defined as 100% and 0%, respectively was drawn. Thus, 10 plotted diagrams were obtained. FIG. 5 is one plotted diagram out of the 10 plotted diagrams.

The number N (times) of times of the light-and-dark switching was determined from the resultant 10 plotted diagrams. As a result, the N was equal to 24.

Next, the number of times of light-and-dark switching in a line segment having a length of 2 mm, which was drawn in a crossed-Nicols image obtained by the observation of each of regions including sites located in upward, downward, leftward, and rightward directions from the central portion when the surface of the first surface of the wafer (C1) was viewed from a planar direction, the sites being each distant from the outer periphery of the first surface by 10 mm, with the polarizing microscope, was measured, and the crossed-Nicols images and plotted diagrams were obtained in the same manner as that described above, followed by the determination of the numbers “a” (times), “b” (times), “c” (times), and “d” (times) of times of the light-and-dark switching. As a result, the “a”, the “b”, the “c”, and the “d” were equal to 18, 26, 8, and 28, respectively, and the change ratios of the “a”, the “b”, the “c”, and the “d” with respect to the N were 25%, 8%, 67%, and 16%, respectively.

Eleven wafers were further produced by the same production method as that for the wafer (C1). There were measurement points in which the number N (times) of times of the light-and-dark switching of each of the resultant 12 wafers was 29 or less, and the change ratio of the number of times of switching in each of the upward, downward, leftward, and rightward directions of the wafer with respect to the number of times of switching in the center thereof was more than 20%. The occurrence ratio of a crack and a fracture in the 12 samples including the wafer (C1) was 33%.

The Group-III element nitride semiconductor substrate according to the embodiment of the present invention may be utilized as each of the substrates of various semiconductor devices.

What is claimed is:

1. A Group-III element nitride semiconductor substrate, comprising:
a first surface; and
a second surface,
wherein the Group-III element nitride semiconductor substrate has a thickness of 200 μm or more, and
wherein the number N of times of light-and-dark switching in a line segment having a length of 2 mm, which is drawn in a crossed-Nicols image obtained by observation of a region including a central portion of a surface of the first surface with a polarizing microscope, is 50 or more.

2. A Group-III element nitride semiconductor substrate, comprising:
a first surface; and
a second surface,
wherein the Group-III element nitride semiconductor substrate has a thickness of 200 μm or more, and
wherein when the number of times of light-and-dark switching in a line segment having a length of 2 mm, which is drawn in a crossed-Nicols image obtained by observation of a region including a central portion of a surface of the first surface with a polarizing microscope, is represented by N,
the number of times of light-and-dark switching in a line segment having a length of 2 mm, which is drawn in a crossed-Nicols image obtained by observation of a region including a site located in a rightward direction from the central portion when the surface of the first surface is viewed from a planar direction, the site being distant from an outer periphery of the first surface by 10 mm, with the polarizing microscope, is represented by “a”,
the number of times of light-and-dark switching in a line segment having a length of 2 mm, which is drawn in a crossed-Nicols image obtained by observation of a region including a site located in a leftward direction from the central portion when the surface of the first surface is viewed from the planar direction, the site being distant from the outer periphery of the first surface by 10 mm, with the polarizing microscope, is represented by “b”,
the number of times of light-and-dark switching in a line segment having a length of 2 mm, which is drawn in a crossed-Nicols image obtained by observation of a region including a site located in an upward direction from the central portion when the surface of the first surface is viewed from the planar direction, the site being distant from the outer periphery of the first surface by 10 mm, with the polarizing microscope, is represented by “c”, and
the number of times of light-and-dark switching in a line segment having a length of 2 mm, which is drawn in a crossed-Nicols image obtained by observation of a region including a site located in a downward direction from the central portion when the surface of the first surface is viewed from the planar direction, the site being distant from the outer periphery of the first surface by 10 mm, with the polarizing microscope, is represented by “d”,
a change ratio of each of the “a”, the “b”, the “c”, and the “d” with respect to the N is 20% or less.

3. The Group-III element nitride semiconductor substrate according to claim 1, wherein a maximum length between points of the light-and-dark switching is 700 μm or less.

4. The Group-III element nitride semiconductor substrate according to claim 2, wherein a maximum length between points of the light-and-dark switching is 700 μm or less.

5. The Group-III element nitride semiconductor substrate according to claim 1, wherein the substrate has a diameter of 45 mm or more.

6. The Group-III element nitride semiconductor substrate according to claim 2, wherein the substrate has a diameter of 45 mm or more.

7. A bonded substrate, comprising:
the Group-III element nitride semiconductor substrate of claim 1; and
a support substrate bonded thereto.

8. A bonded substrate, comprising:
the Group-III element nitride semiconductor substrate of claim 2; and
a support substrate bonded thereto.
